(19) United States
(12) Patent Application Publication
(10) Pub. No.: US 2025/0218999 A1
(43) Pub. Date: Jul. 3, 2025

(54) PASSIVE COMPONENT ASSEMBLY FOR THICKNESS MODIFICATION TO MATCH CORE THICKNESS

(71) Applicant: Intel Corporation, Santa Clara, CA (US)

(72) Inventors: Bohan SHAN, Chandler, AZ (US); Hongxia FENG, Chandler, AZ (US); Jose WAIMIN, Gilbert, AZ (US); Ryan CARRAZZONE, Chandler, AZ (US); Kyle ARRINGTON, Gilbert, AZ (US); Ziyin LIN, Chandler, AZ (US); Dingying David XU, Chandler, AZ (US); Yongki MIN, Phoenix, AZ (US); Srinivas Venkata Ramanuja PIETAMBARAM, Chandler, AZ (US); Gang DUAN, Chandler, AZ (US); Wei LI, Chandler, AZ (US); Ashay DANI, Chandler, AZ (US); Leonel R. ARANA, Phoenix, AZ (US); Brandon C. MARIN, Gilbert, AZ (US); Clay ARRINGTON, Queen Creek, AZ (US); Hiroki TANAKA, Gilbert, AZ (US); Haobo CHEN, Chandler, AZ (US); Mohit GUPTA, Chandler, AZ (US)

(21) Appl. No.: 18/398,827

(22) Filed: Dec. 28, 2023

(51) Int. Cl. H01L 23/00; H01L 23/498; H05K 3/46

(52) U.S. Cl. CPC H01L 24/16; H01L 23/49822; H01L 23/49838; H01L 24/32; H05K 3/4644; H01L 2224/16225; H01L 2224/32225; H01L 2924/19041

(57) ABSTRACT

Embodiments disclosed herein include passive electrical components with thickness modifications. In an embodiment, such an apparatus may comprise a first substrate with a first material composition, where the first substrate comprises a passive electrical device. In an embodiment, a second substrate is coupled to the first substrate, where the second substrate has a second material composition. In an embodiment, a layer is over a surface of the second substrate opposite from the first substrate, and the layer is electrically insulating.

### BACKGROUND

As advanced packaging is enabling more aggressive computation capability, high power and high quality power delivery is needed to support all of the overlying chiplets. The ability to embed passive components (e.g., capacitors, inductors, resistors, etc.) into the package substrate will enable improved performance compared to placing the passive components on the land side of the package. Embedding components in the core is beneficial because there is less routing in the core compared to overlying and underlying buildup layers. As such, space within the package substrate is more fully utilized.

However, substrate core thickness is defined by the total package thermomechanical stress level. This required thickness can be significantly different than the thickness of the passive component. For example, in the case of a deep trench capacitor (DTC), the DTC is fabricated on a silicon wafer. The wafer will have a thickness that is potentially hundreds of microns different than the thickness of the core, which can be approximately 1.0 mm or greater. Placing such passive components in deep cavities through the core can be problematic. For example, the passive components may shift or rotate during embedding.

### BRIEF DESCRIPTION OF THE DRAWINGS

FIG. 1 is a cross-sectional illustration of a core with an embedded passive component that has shifted during the embedding process, in accordance with an embodiment.

FIG. 2A is a cross-sectional illustration of a portion of a package substrate that includes an embedded assembly with a component substrate that is directly bonded to a spacer substrate, in accordance with an embodiment.

FIG. 2B is a cross-sectional illustration of a portion of a package substrate that includes an embedded assembly with a component substrate that is bonded to a spacer substrate with an adhesive layer, in accordance with an embodiment.

FIG. 2C is a cross-sectional illustration of a portion of a package substrate that includes an embedded assembly with a component substrate that is bonded to a spacer substrate with a solder, in accordance with an embodiment.

FIGS. 3A-3F are cross-sectional illustrations depicting a process for forming assemblies with component substrates directly bonded to spacer substrates using wafer level processes, in accordance with an embodiment.

FIG. 3G is a process flow diagram depicting a wafer level process for forming assemblies with component substrates bonded to spacer substrates, in accordance with an embodiment.

FIGS. 4A-4C are cross-sectional illustrations depicting a process for forming assemblies with component substrates bonded to spacer substrates with an adhesive using a wafer level process, in accordance with an embodiment.

FIG. 4D is a process flow diagram depicting a wafer level process for forming assemblies with component substrates bonded to spacer substrates, in accordance with an embodiment.

FIGS. 5A-5D are cross-sectional illustrations depicting a process for forming assemblies with component substrates bonded to spacer substrates, in accordance with an embodiment.

FIG. 5E is a process flow diagram depicting a wafer level process for forming assemblies with component substrates bonded to spacer substrates, in accordance with an embodiment.

FIGS. 6A-6E are cross-sectional illustrations depicting a process for forming a portion of a package substrate with an assembly with a component substrate and a spacer embedded in a core of the package substrate, in accordance with an embodiment.

FIG. 6F is a process flow diagram depicting a process for assembling a package substrate with an assembly embedded in a core of the package substrate, in accordance with an embodiment.

FIG. 7 is a cross-sectional illustration of an electronic system that comprises a package substrate with an assembly embedded in a core of the package substrate, in accordance with an embodiment.

FIG. 8 is a schematic of a computing device built in accordance with an embodiment.

### EMBODIMENTS OF THE PRESENT DISCLOSURE

Described herein are electronic systems, and more particularly, passive component assemblies that have dummy structures for thickness modification, in accordance with various embodiments. In the following description, various aspects of the illustrative implementations will be described using terms commonly employed by those skilled in the art to convey the substance of their work to others skilled in the art.

However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

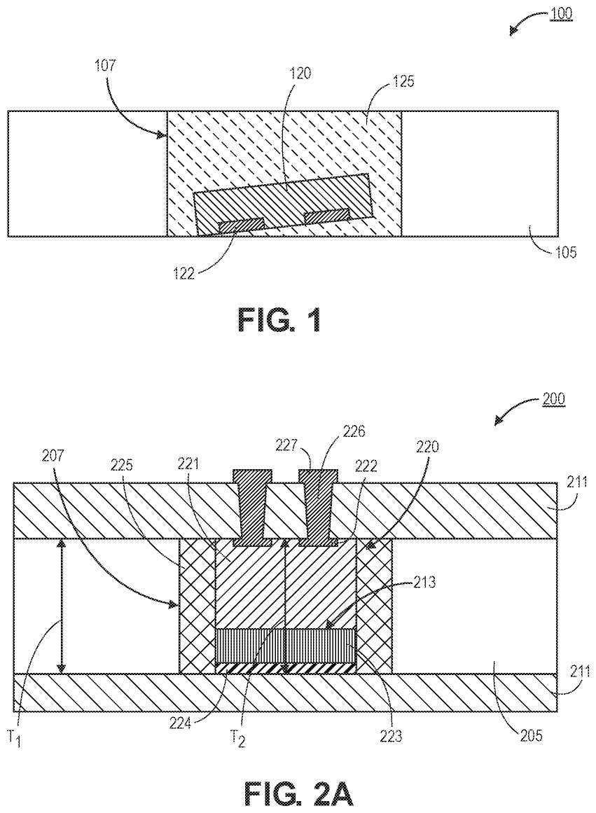

As noted above, introducing passive components (e.g., inductors, capacitors, resistors, etc.) into the package substrate is desirable to improve power delivery and performance for the overlying chiplets compared to placing the passive components on the land side of the package substrate. This is due, at least in part, to the passive components being physically closer to the chiplets when they are integrated into the package substrate. One suitable location in the package substrate for the passive components is the core. The core has underutilized space that can be leveraged to house the passive components. However, the thickness of the passive components is usually smaller than a thickness of the core. This can lead to integration and manufacturing issues. Examples of these drawbacks can be seen in FIG. 1.

Referring now to FIG. 1, a cross-sectional illustration of a portion of a package substrate 100 is shown, in accordance with an embodiment. The package substrate 100 may comprise a core 105. The core 105 may sometimes be referred to simply as a substrate. The core 105 may be a glass core, an organic core, or the like. In an embodiment, a cavity 107 passes at least partially through the core 105. For example, in FIG. 1 the cavity 107 passes entirely through the core 105.

In an embodiment, a component 120 is provided in the cavity 107. The component 120 may have a thickness that is smaller than a thickness of the core 105. For example, the component 120 may have a thickness that is hundreds of microns thinner than the core 105. The component 120 is secured within the cavity 107 through the use of a fill layer 125. The fill layer 125 may be a dielectric material, such as a mold layer, an epoxy, an adhesive, or the like. However, during the filling process, the component 120 may shift and/or rotate. The movement of the component 120 may be due, at least in part, to the introduction of pressure to the component 120 during the filling process. As shown, the component 120 has tilted so that one side is raised up from the bottom of the core 105. This may make it difficult to make electrical contact to the pads 122 that are at the bottom of the component 120 in subsequent processing operations.

Accordingly, embodiments disclosed herein reduce movement of the electrically passive component by providing assemblies that include a component substrate that is mounted to an underlying spacer substrate. In some embodiments, the spacer substrate may be referred to as a dummy substrate (since there may be no active circuitry in the substrate). More particularly, the assemblies may be fabricated using wafer level processes in order to improve capacity and reduce assembly costs. The wafer level processes may include several different bonding solutions.

In one solution, the assembly may include a component substrate that is fusion bonded to the spacer substrate. That is, the component substrate and the spacer substrate may be directly contacting each other in some embodiment. In another solution, an adhesive layer may be provided between the component substrate and the spacer substrate. In yet another embodiment, the component substrate and the spacer substrate may have backside metallizations so that a solder may be used to couple the component substrate to the spacer substrate. After the wafer level processing, the substrates can be singulated in order to form individual assemblies.

In an embodiment, the assemblies may be inserted into cavities that are provided through the core of the package substrate. A thickness of the assemblies may be substantially equal to a thickness of the core. As used herein, “substantially equal” may refer to two values that are within ten percent of each other. For example, a first thickness between 900 μm and 1,000 μm may be substantially equal to a second thickness that is 1,000 μm. In an embodiment, the thickness of the assembly may be set by choosing a particular spacer substrate thickness. In an embodiment, the spacer substrate may also be thinned or reduced in thickness after being coupled to the component substrate.

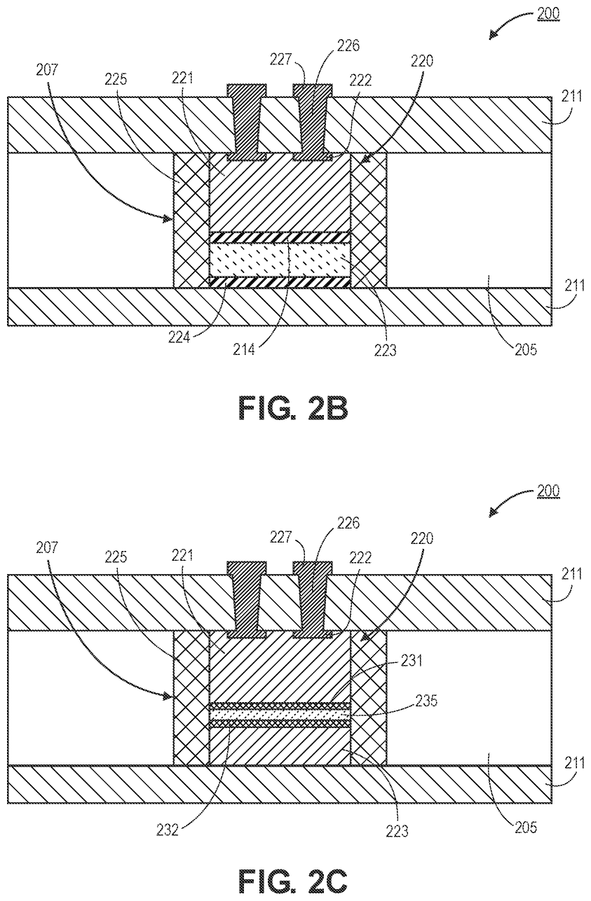

Referring now to FIG. 2A, a cross-sectional illustration of a portion of a package substrate 200 is shown, in accordance with an embodiment. In an embodiment, the package substrate 200 may comprise a core 205. The core 205 may be an organic core 205 or a glass core 205. In the case of a glass core 205, the glass core 205 may be substantially all glass. The glass core 205 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, glass core 205 may be distinguished from, for example, the “prepreg” or “RF4” core of a Printed Circuit Board (PCB) substrate which typically comprises glass fibers embedded in a resinous organic material, such as an epoxy.

The glass core 205 may have any suitable dimensions. In a particular embodiment, the glass core 205 may have a thickness that is approximately 50 μm or greater. For example, the thickness of the glass core 205 may be between approximately 50 μm and approximately 1.4 mm. Though, smaller or larger thicknesses may also be used. The glass core 205 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the glass core 205 (from an overhead plan view) may be between approximately 10 mm×10 mm and approximately 250 mm×250 mm. In an embodiment, the glass core 205 may have a first side that is perpendicular or orthogonal to a second side. In a more general embodiment, the glass core 205 may comprise a rectangular prism volume with sections (e.g., vias) removed and filled with other materials (e.g., metal, etc.).

The glass core 205 may comprise a single monolithic layer of glass. In other embodiments, the glass core 205 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core 205 may each have a thickness less than approximately 50 μm. For example, discrete layers of glass in the glass core 205 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The glass core 205 may be any suitable glass formulation that has the necessary mechanical robustness and compatibility with semiconductor packaging manufacturing and assembly processes. For example, the glass core 205 may comprise aluminosilicate glass, borosilicate glass, alumino-borosilicate glass, silica, fused silica, or the like. In some embodiments, the glass core 205 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass core 205 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core 205 may comprise at least 23 percent silicon (by weight) and at least 26 percent oxygen (by weight). In some embodiments, the glass core 205 may further comprise at least 5 percent aluminum (by weight).

In an embodiment, a cavity 207 may be provided through a thickness of the core 205. The cavity 207 may have sidewalls that are substantially vertical. Though, in other embodiments, the cavity 207 may have tapered, sloped, or otherwise non-planar sidewalls.

In an embodiment, an assembly 220 is inserted into the cavity 207. The core 205 may have a first thickness T₁ and the assembly 220 may have a second thickness T₂ that is substantially equal to the first thickness T₁. As such, embedding the assembly 220 with the fill layer 225 may not significantly move, displace, and/or rotate the assembly 220. The fill layer 225 may be a mold material, an epoxy, an organic dielectric (e.g., a buildup film), or the like. In some embodiments, the fill layer 225 may be the same material as the buildup layers 211 above and/or below the core 205. Though, the fill layer 225 may also be a different material than the buildup layers 211.

In an embodiment, the assembly 220 may comprise a component substrate 221. The component substrate 221 may comprise one or more passive electrical devices (not shown). For example, the component substrate 221 may comprise one or more of an inductor, a capacitor, a resistor, or the like. In a particular embodiment, the component substrate 221 is a deep trench capacitor (DTC). The component substrate 221 may comprise any suitable material, such as a semiconductor (e.g., silicon), a glass, a ceramic, an organic dielectric, or the like. Other than pads 222, the component substrate 221 is shown as being a monolithic structure. That is, electrical routing, pads, plates, electrodes, vias, high-k dielectrics (e.g., for capacitors), magnetic material (e.g., for inductors), and other structures are omitted for simplicity. However, it is to be appreciated that these structures and any other necessary structures for enabling passive electrical devices may be integrated into or provided on the component substrate 221.

In an embodiment, the assembly 220 may further comprise a spacer substrate 223 that is coupled to the component substrate 221. In an embodiment, the spacer substrate 223 may comprise the same material as the component substrate 221. For example, the component substrate 221 and the spacer substrate 223 may both comprise silicon. In some embodiments, the component substrate 221 is fusion bonded to the spacer substrate 223. A seam 213 may be visible at the fusion bonded interface in some embodiments. Though, in other instances, there may not be a visible seam 213.

In an embodiment, the spacer substrate 223 may be a monolithic substrate without any integrated features or components. That is, the spacer substrate 223 may be a solid rectangular prism or other three dimensional shape. Since there may not be any functional electrical circuitry within the spacer substrate 223, the spacer substrate 223 may sometimes be referred to as a dummy substrate.

In an embodiment, a layer 224 may be provided between the spacer substrate 223 and the underlying buildup layer 211. The layer 224 may be an adhesive layer or any other material that can help to secure the assembly 220 during the assembly process. Though, in other embodiments, the layer 224 may be omitted. That is, the spacer substrate 223 may directly contact the buildup layer 211 in some embodiments.

In an embodiment, the pads 222 of the component substrate 221 may be electrically coupled to external devices or circuitry (not shown) by vias 226, pads 227, and/or the like. In some instances, the vias 226, pads 227, and the like may be fabricated along with the fabrication of the buildup layers 211 using typical processing for package substrate 200 fabrication.

Referring now to FIG. 2B, a cross-sectional illustration of a portion of a package substrate 200 is shown, in accordance with an additional embodiment. In an embodiment, the package substrate 200 in FIG. 2B may be similar to the package substrate 200 in FIG. 2A, with the exception of the structure of the assembly 220. Instead of a direct bonding (e.g., fusion bonding) between the component substrate 221 and the spacer substrate 223, an adhesive layer 214 may be provided between the component substrate 221 and the spacer substrate 223. Since an adhesive layer 214 is used, the component substrate 221 and the spacer substrate 223 may comprise different material compositions. For example, the component substrate 221 may comprise silicon, and the spacer substrate 223 may comprise glass, ceramic, metal, or the like. The flexibility in material choice for the spacer substrate 223 may also simplify assembly of the assembly 220. For example, a greater selection of spacer substrate 223 thicknesses may be available, and subsequent thinning or polishing may not be necessary.

Referring now to FIG. 2C, a cross-sectional illustration of a portion of a package substrate 200 is shown, in accordance with yet another embodiment. In an embodiment, the package substrate 200 in FIG. 2C may be similar to the package substrate 200 in FIG. 2A, with the exception of the interface between the component substrate 221 and the spacer substrate 223. Instead of a fusion bonded interface, a solder layer 235 may be used. The solder layer 235 may be accommodated by metallizing surfaces of the component substrate 221 and the spacer substrate 223. For example, metal layer 231 may be provided on the component substrate 221, and metal layer 232 may be provided on the spacer substrate 223.

In an embodiment, the metallization to form the metal layers 231 and 232 may include any suitable metallic material or materials. In a particular embodiment, the metal layers 231 may comprise titanium, nickel, and/or gold (e.g., a TiNiAu alloy). In some instances, the metal layers 231 and 232 may each comprise a single layer with a single material composition. In other embodiments, one or both of the metal layers 231 or 232 may comprise sub-layers, with each sub-layer having a different composition. Sub-layer configurations may be useful for improving adhesion between the substrates 221 or 223 and the solder layer 235. For example, a first sub-layer may have high adhesion strength with silicon, a second sub-layer may have high adhesion strength with the first sub-layer, and a third sub-layer may have high adhesion strength with the second sub-layer and with the solder layer 235.

In an embodiment, the solder layer 235 may be any suitable solder material. That is, the solder layer 235 may have a metallic composition that has a melting temperature that is below a melting temperature of the metal layers 231 and 232. In one embodiment, the solder layer 235 may include an alloy comprising tin, silver, and copper (e.g., a SAC solder), the solder layer 235 may include an alloy comprising indium with silver or gold (e.g., an In—Ag solder or an In—Au solder), or the solder layer 235 may comprise any suitable low temperature solder (LTS), such as one comprising bismuth.

In the illustrated embodiment, the spacer substrate 223 is directly supported on the underlying buildup layer 211. Though, in other embodiments, an adhesive layer (not shown) or the like may be provided between the spacer substrate 223 and the underlying buildup layer 211.

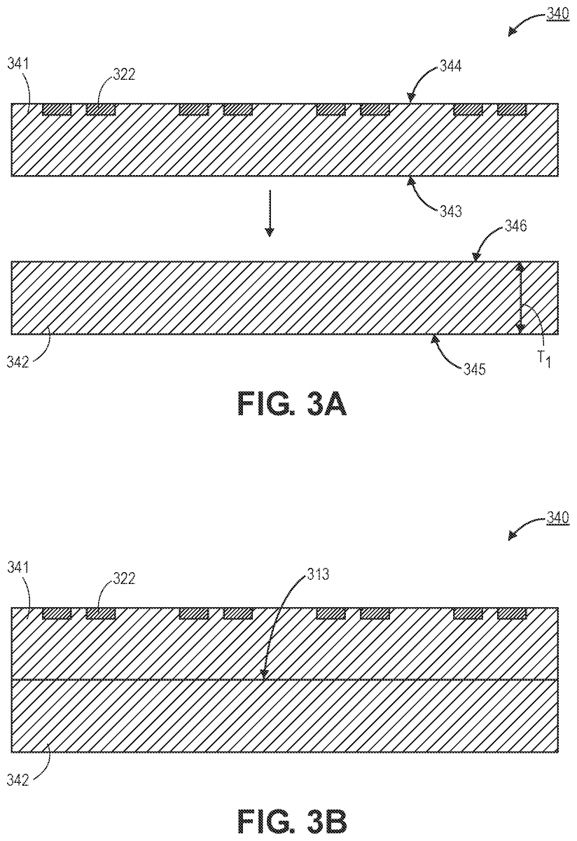

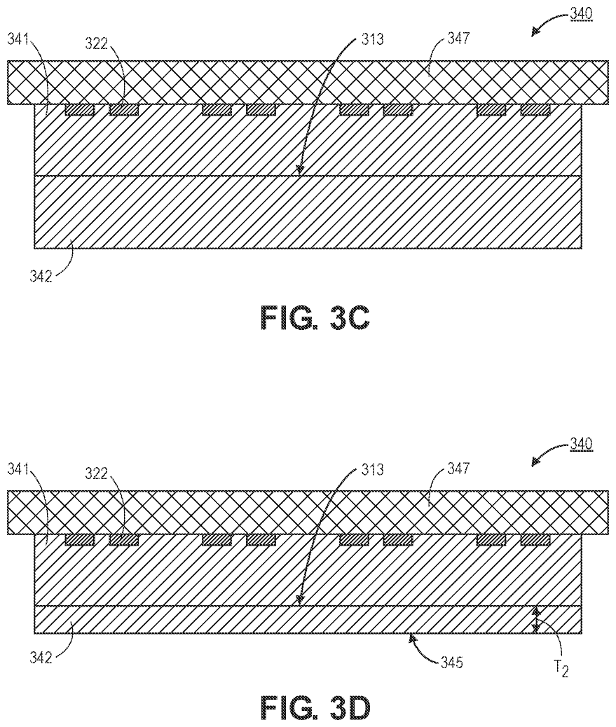

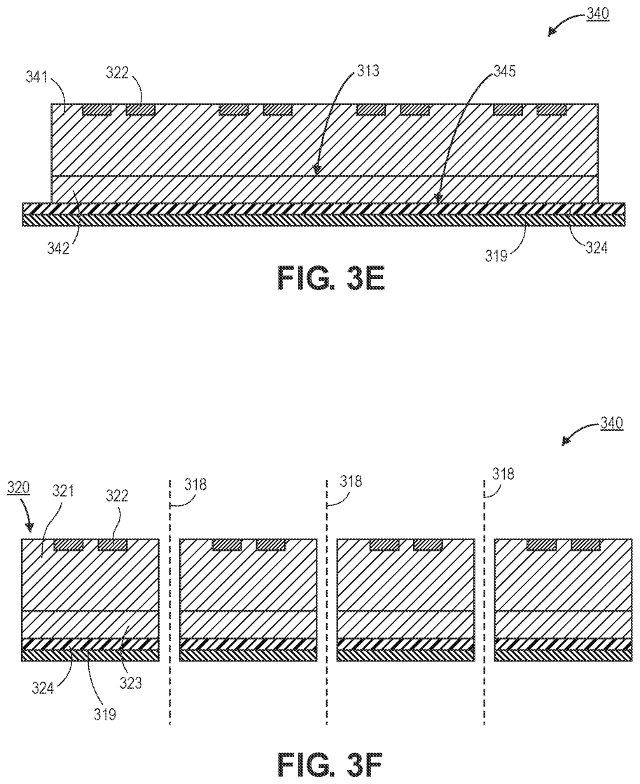

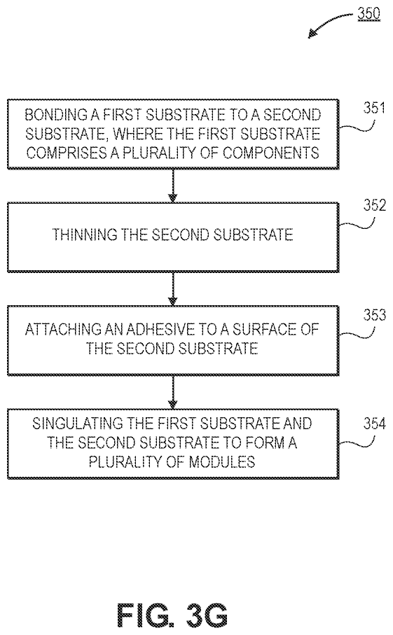

Referring now to FIGS. 3A-3F, a series of cross-sectional illustrations depicting a process for forming an assembly 320 using a wafer level process is shown, in accordance with an embodiment. In the embodiment shown in FIGS. 3A-3F, the wafer level process includes a fusion bonding operation between a component wafer and a spacer wafer.

Referring now to FIG. 3A, a cross-sectional illustration of an assembly 340 is shown, in accordance with an embodiment. In an embodiment, the assembly 340 may comprise a component wafer 341 and a spacer wafer 342. The component wafer 341 may comprise a first surface 343 and a second surface 344 opposite from the first surface 343. In an embodiment, pads 322 may be provided at the second surface 344 of the component wafer 341. The component wafer 341 may include a plurality of electrically passive devices (e.g., inductors, capacitors, resistors, etc.). The structures of the electrically passive devices are omitted from the Figures for simplicity.

In an embodiment, the spacer wafer 342 may comprise a first surface 345 and a second surface 346 opposite from the first surface 345. In an embodiment, the spacer wafer 342 may include no electrical routing or other integrated features. That is, the spacer wafer 342 may be a dummy wafer in some instances. The spacer wafer 342 may have a first thickness T₁. In an embodiment, the spacer wafer 342 may have a material composition that is the same or similar to a material composition of the component wafer 341. For example, both the spacer wafer 342 and the component wafer 341 may comprise silicon.

As indicated by the arrow, the spacer wafer 342 and the component wafer 341 are brought together so that first surface 343 of the component wafer 341 contacts the second surface 346 of the spacer wafer 342. A fusion bonding process may then be used in order to couple the two wafers 341 and 342 together.

Referring now to FIG. 3B, a cross-sectional illustration of the assembly 340 after the fusion bonding is shown, in accordance with an embodiment. The assembly 340 may include a seam 313 between the component wafer 341 and the spacer wafer 342. The seam 313 may be an indication that a fusion bonding process was used. For example, the component wafer 341 may directly contact the spacer wafer 342 at the seam 313.

Referring now to FIG. 3C, a cross-sectional illustration of the assembly 340 after a carrier 347 is added to the top of the component wafer 341 is shown, in accordance with an embodiment. The carrier 347 may be a glass material, a ceramic material, a metal material, or the like. The carrier 347 may be a substrate that is suitable for retaining the assembly 340 during subsequent processing.

Referring now to FIG. 3D, a cross-sectional illustration of the assembly 340 after the spacer wafer 342 is thinned is shown, in accordance with an embodiment. In an embodiment, the thinning process may result in the recessing of the first surface 345 of the spacer wafer 342. The thinning may be done with a chemical mechanical polishing (CMP) process, or the like. The thinning process may result in a reduction in the thickness of the spacer wafer 342. For example, the spacer wafer 342 may now have a second thickness T₂ that is smaller than the first thickness T₁.

Referring now to FIG. 3E, a cross-sectional illustration of the assembly 340 after an adhesive layer 324 is applied to the first surface 345 of the spacer wafer 342 is shown, in accordance with an embodiment. In an embodiment, the adhesive layer 324 may have a backing layer 319 to prevent the adhesive layer 324 from sticking to unintended surfaces. The adhesive layer 324 may be applied before or after the carrier 347 is removed.

Referring now to FIG. 3F, a cross-sectional illustration of the assembly 340 after singulation is shown, in accordance with an embodiment. As shown, the assembly 340 may be singulated along lines 318 into a plurality of assemblies 320. Each assembly 320 may include a component substrate 321 that is fusion bonded to a spacer substrate 323. The component substrate 321 may include one or more electrically passive devices (not shown) such as an inductor, a capacitor, a resistor, or the like. The singulation process may include sawing, etching, laser ablation, or any other suitable process.

Referring now to FIG. 3G, a process flow diagram depicting a process 350 for fabricating an assembly with a wafer level process is shown, in accordance with an embodiment. In an embodiment, the process 350 may begin with operation 351, which comprises bonding a first substrate to a second substrate. In an embodiment, the first substrate comprises a plurality of components. In an embodiment, the bonding process may be similar to the bonding process described and illustrated with respect to FIGS. 3A and 3B above.

In an embodiment, the process 350 may continue with operation 352, which comprises thinning the second substrate. In an embodiment, the thinning operation may be similar to the thinning described and illustrated with respect to FIG. 3D above.

In an embodiment, the process 350 may continue with operation 353, which comprises attaching an adhesive to a surface of the second substrate. The adhesive attachment may be similar to the process described and illustrated with respect to FIG. 3E above.

In an embodiment, the process 350 may continue with operation 354, which comprises singulating the first substrate and the second substrate to from a plurality of assemblies. The singulation process may be similar to the process described and illustrated with respect to FIG. 3F above.

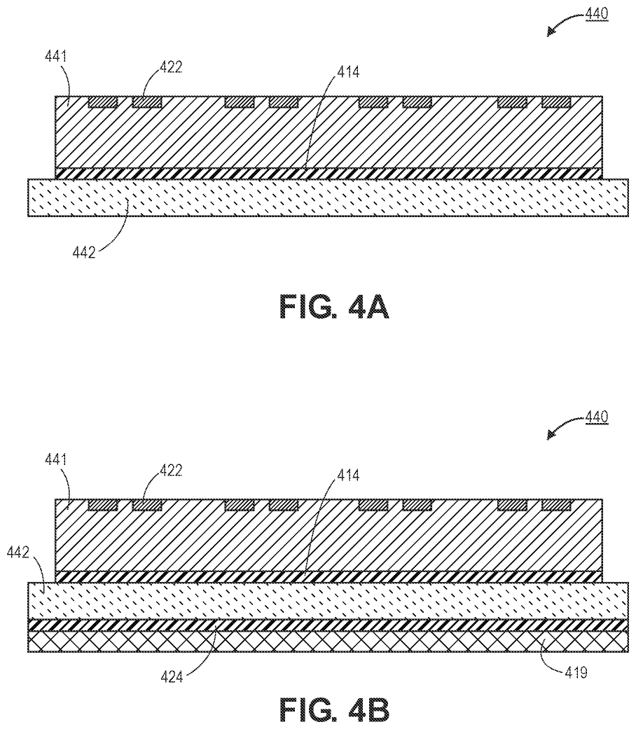

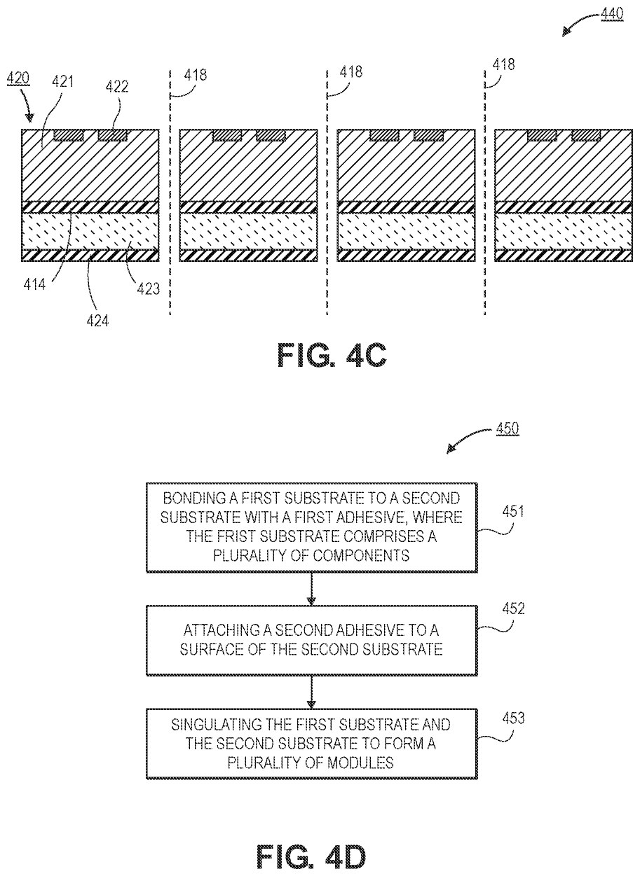

Referring now to FIGS. 4A-4C, a series of cross-sectional illustrations depicting a process for forming assemblies with a wafer level process is shown, in accordance with an embodiment. The assemblies may include a component substrate 421 that is coupled to a spacer substrate 423 by an adhesive layer 414.

Referring now to FIG. 4A, a cross-sectional illustration of an assembly 440 is shown, in accordance with an embodiment. In an embodiment, the assembly 440 may comprise a component wafer 441. In an embodiment, pads 422 may be provided on the component wafer 441. The component wafer 441 may include a plurality of electrically passive devices (e.g., inductors, capacitors, resistors, etc.). The structures of the electrically passive devices are omitted from the Figures for simplicity. In an embodiment, a spacer wafer 442 may be coupled to the component wafer 441 by an adhesive layer 414. The spacer wafer 442 may be a different material than the component wafer 441. The spacer wafer 442 may comprise silicon, glass, a ceramic, metal, or the like. The spacer wafer 442 may not have any integrated circuitry or other features. For example, the spacer wafer 442 may be considered as a dummy wafer.

Referring now to FIG. 4B, a cross-sectional illustration of the assembly 440 after a second adhesive 424 is attached to the spacer wafer 442 is shown, in accordance with an embodiment. In an embodiment the second adhesive 424 may have a backing layer 419 to prevent sticking to unintended surfaces.

Referring now to FIG. 4C, a cross-sectional illustration of the assembly 440 after singulation is shown, in accordance with an embodiment. As shown, the assembly 440 may be singulated along lines 418 into a plurality of assemblies 420. Each assembly 420 may include a component substrate 421 that is bonded to a spacer substrate 423 by an adhesive layer 414. The component substrate 421 may include one or more electrically passive devices (not shown) such as an inductor, a capacitor, a resistor, or the like. The singulation process may include sawing, etching, laser ablation, or any other suitable process.

Referring now to FIG. 4D, a process flow diagram depicting a process 450 for forming an assembly with a wafer level process is shown, in accordance with an embodiment. In an embodiment, the process 450 may begin with operation 451, which comprises bonding a first substrate to a second substrate with a first adhesive. In an embodiment, the first substrate may comprise a plurality of components. The operation 451 may be similar to the process and structure described herein with respect to FIG. 4A.

In an embodiment, the process 450 may continue with operation 452, which comprises attaching a second adhesive to a surface of the second substrate. The operation 452 may be similar to the process and structure described herein with respect to FIG. 4B

In an embodiment, the process 450 may continue with operation 453, which comprises singulating the first substrate and the second substrate to form a plurality of assemblies. The operation 453 may be similar to the process and structure described herein with respect to FIG. 4C.

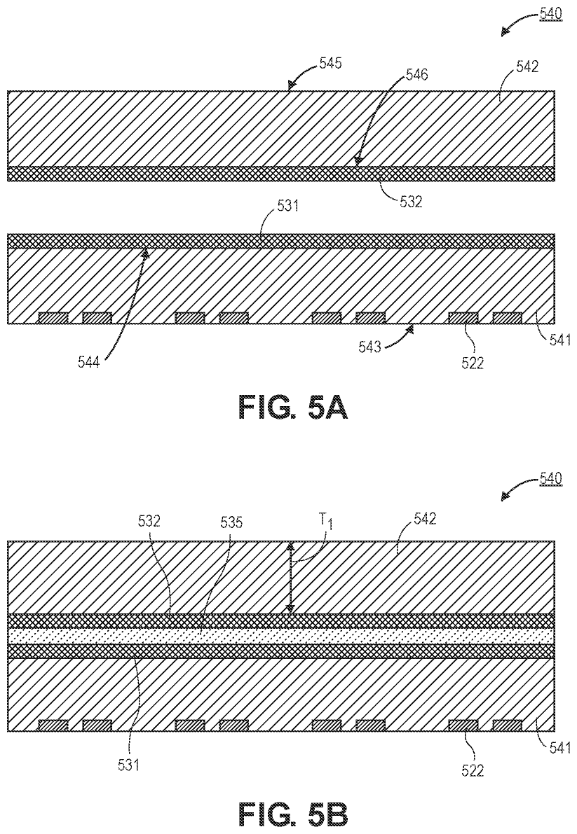

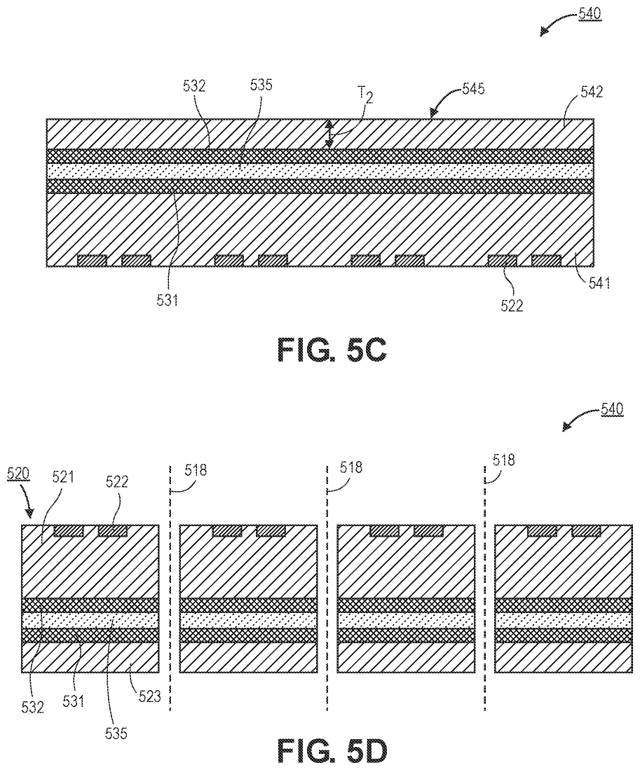

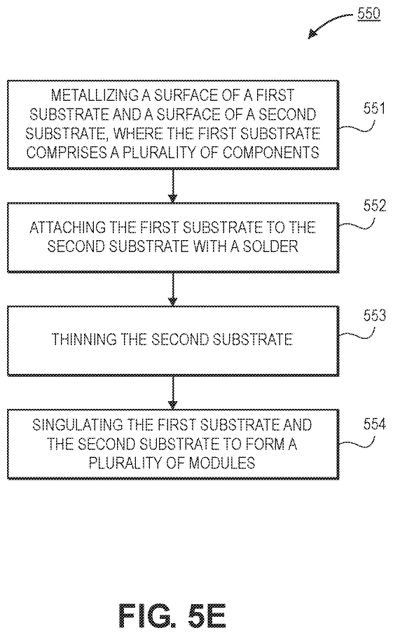

Referring now to FIGS. 5A-5D, a series of cross-sectional illustrations depicting a process for forming assemblies with a wafer level process is shown, in accordance with an embodiment. The assemblies may include a component substrate 521 that is coupled to a spacer substrate 523 by a solder layer 535.

Referring now to FIG. 5A, a cross-sectional illustration of an assembly 540 is shown, in accordance with an embodiment. In an embodiment, the assembly 540 may comprise a component wafer 541 and a spacer wafer 542. The component wafer 541 may comprise a first surface 543 and a second surface 544 opposite from the first surface 543. In an embodiment, pads 522 may be provided at the first surface 543 of the component wafer 541. The component wafer 541 may include a plurality of electrically passive devices (e.g., inductors, capacitors, resistors, etc.). The structures of the electrically passive devices are omitted from the Figures for simplicity.

In an embodiment, the spacer wafer 542 may comprise a first surface 545 and a second surface 546 opposite from the first surface 545. In an embodiment, the spacer wafer 542 may include no electrical routing or other integrated features. That is, the spacer wafer 542 may be a dummy wafer in some instances.

In an embodiment, a first metal layer 531 may be provided on the second surface 544 of the component wafer 541, and a second metal layer 532 may be provided on the second surface 546 of the spacer wafer 542. The metal layers 531 and 532 may be any typical backside metallization layer compositions typical of semiconductor fabrication. For example, the metal layers 531 and 532 may comprise one or more of titanium, nickel, and/or gold. The metal layers 531 and 532 may be applied with sputtering, or any other suitable deposition process.

Referring now to FIG. 5B, a cross-sectional illustration of the assembly 540 after the component wafer 541 is bonded to the spacer wafer 542 is shown, in accordance with an embodiment. In an embodiment, a solder layer 535 may be used to connect the metal layers 531 and 532 together. In an embodiment, the solder layer 535 may be a solder preform, a solder paste, or a plated solder. In an embodiment, the solder layer 535 may include an alloy comprising tin, silver, and copper (e.g., a SAC solder), the solder layer 535 may include an alloy comprising indium with silver or gold (e.g., an In—Ag solder or an In—Au solder), or the solder layer 535 may comprise any suitable low temperature solder (LTS), such as one comprising bismuth. In an embodiment, the spacer wafer 542 may have a first thickness T₁.

Referring now to FIG. 5C, a cross-sectional illustration of the assembly 540 after a thinning process is used to reduce a thickness of the spacer wafer 542 is shown, in accordance with an embodiment. In an embodiment, the thinning process may result in the recessing of the first surface 545 of the spacer wafer 542. The thinning may be done with a CMP process, or the like. The thinning process may result in a reduction in the thickness of the spacer wafer 542. For example, the spacer wafer 542 may now have a second thickness T₂ that is smaller than the first thickness T₁.

Referring now to FIG. 5D, a cross-sectional illustration of the assembly 540 after singulation is shown, in accordance with an embodiment. As shown, the assembly 540 may be singulated along lines 518 into a plurality of assemblies 520. Each assembly 520 may include a component substrate 521 that is bonded to a spacer substrate 523 by a solder layer 535 that is between metal layers 531 and 532. The component substrate 521 may include one or more electrically passive devices (not shown) such as an inductor, a capacitor, a resistor, or the like. The singulation process may include sawing, etching, laser ablation, or any other suitable process.

Referring now to FIG. 5E, a process flow diagram depicting a process 550 for forming an assembly with a wafer level process is shown, in accordance with an embodiment. In an embodiment, the process 550 may begin with operation 551, which comprises metalizing a surface of a first substrate and a surface of a second substrate. In an embodiment, the first substrate may comprise a plurality of components. The operation 551 may be similar to the process and structure described herein with respect to FIG. 5A.

In an embodiment, process 550 may continue with operation 552, which comprises attaching the first substrate to the second substrate with a solder. The operation 552 may be similar to the process and structure described herein with respect to FIG. 5B.

In an embodiment, process 550 may continue with operation 553, which comprises thinning the second substrate. The operation 553 may be similar to the process and structure described herein with respect to FIG. 5C.

In an embodiment, the process 550 may continue with operation 554, which comprises singulating the first substrate and the second substrate to form a plurality of assemblies. The operation 553 may be similar to the process and structure described herein with respect to FIG. 5D.

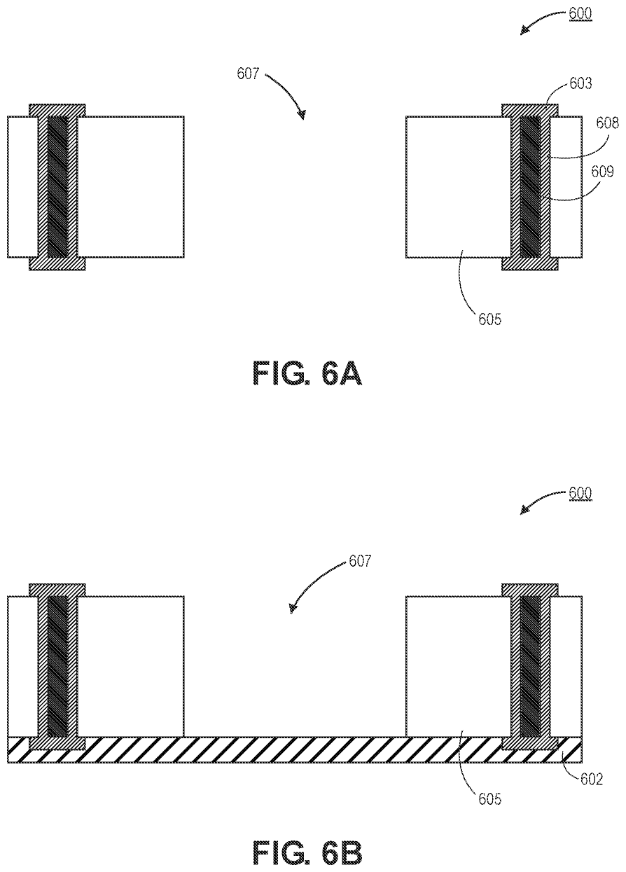

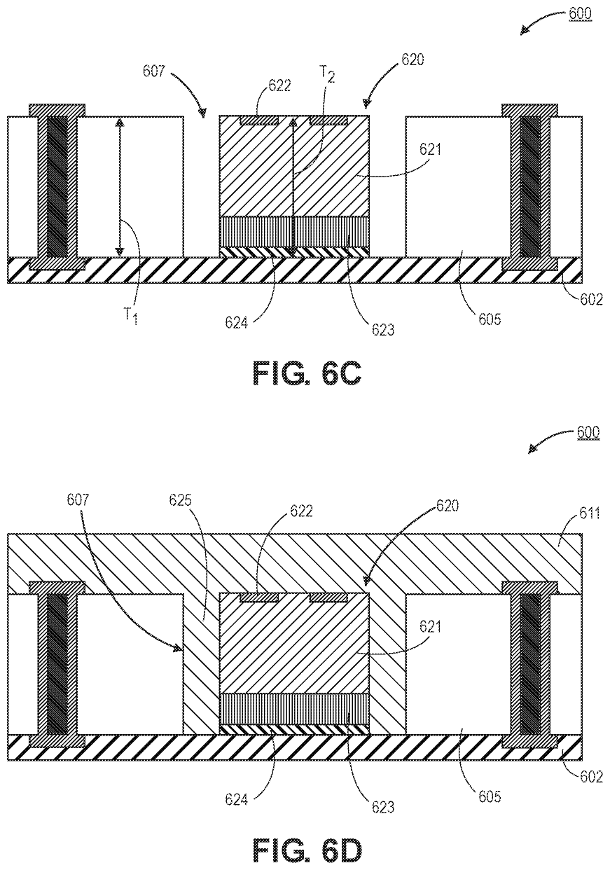

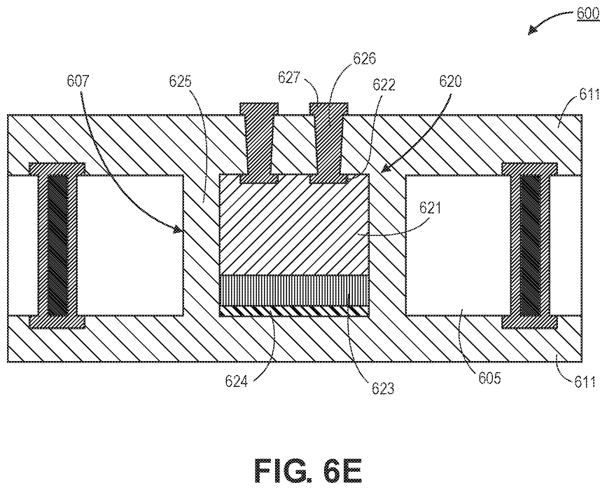

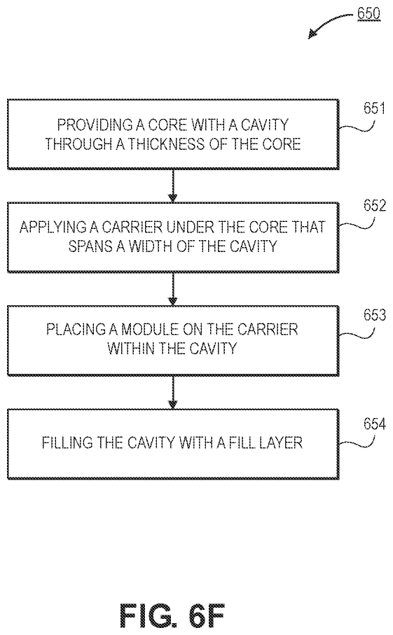

Referring now to FIGS. 6A-6E, a series of cross-sectional illustrations depicting a process for assembling a package substrate 600 with an assembly 620 embedded in the core 605 is shown, in accordance with an embodiment.

Referring now to FIG. 6A, a cross-sectional illustration of a portion of a package substrate 600 is shown, in accordance with an embodiment. In an embodiment, the package substrate 600 comprises a core 605, such as a glass core 605 or an organic core 605. The core 605 may be similar to any core described in greater detail herein. In an embodiment, vias 608 may pass through a thickness of the core 605. The vias 608 in FIG. 6A have a plated through hole (PTH) configuration. That is, the vias 608 are electrically conductive shells with an insulating plug 609. In other embodiments, the vias 608 may be fully filled with electrically conductive material. Pads 603 may be provided above and/or below the vias 608.

In an embodiment, a cavity 607 is provided through a thickness of the core 605. The cavity 607 may have sidewalls that are substantially vertical, as shown in FIG. 6A. In other embodiments, sidewalls of the cavity 607 may be tapered, sloped, or non-planar.

Referring now to FIG. 6B, a cross-sectional illustration of the portion of the package substrate 600 after a tape 602 is applied across a bottom of the core 605 is shown, in accordance with an embodiment. The tape 602 (or other temporary carrier substrate) may span the opening of the cavity 607 in order to provide a surface on which to mount the assembly 620 (not shown in FIG. 6B).

Referring now to FIG. 6C, a cross-sectional illustration of the portion of the package substrate 600 after an assembly 620 is inserted into the cavity 607 is shown, in accordance with an embodiment. In the illustrated embodiment, the assembly 620 has a component substrate 621 with pads 622 that is fusion bonded to a spacer substrate 623. An adhesive 624 may couple the spacer substrate 623 to the tape 602. While a particular assembly 620 structure is shown in FIG. 6C, it is to be appreciated that any assembly structure described herein may be integrated into the package substrate 600. In an embodiment, the core 605 may have a first thickness T₁, and the assembly 620 may have a second thickness T₂. The first thickness T₁ may be substantially equal to the second thickness T₂ in some embodiments.

Referring now to FIG. 6D, a cross-sectional illustration of the portion of the package substrate after the cavity 607 is filled with a layer 625 is shown, in accordance with an embodiment. The layer 625 may include a mold material, an epoxy, an organic dielectric material, or the like. In an embodiment, the layer 625 may be the same material as the buildup layer 611. For example, buildup film may be laminated over the core 605 in order to fill the cavity 607 and form the buildup layer 611. Though, in other embodiments, the layer 625 may be a different material than the buildup layer 611.

Referring now to FIG. 6E, a cross-sectional illustration of the portion of the package substrate 600 after a bottom buildup layer 611 is formed and electrical routing to the pads 622 is provided is shown, in accordance with an embodiment. In an embodiment, the tape 602 is removed, and the buildup layer 611 is laminated over the bottom of the core 605. In an embodiment, vias 626 and pads 627 may be formed so that they are coupled to the pads 622. The vias 626 and pads 627 may be formed with laser ablation and plating processes, or any other suitable process. After the embodiment shown in FIG. 6E, traditional package substrate assembly processes may be used in order to complete the fabrication of the package substrate 600.

Referring now to FIG. 6F, a process flow diagram of a process 650 for assembling a package substrate is shown, in accordance with an embodiment. In an embodiment, the process 650 may begin with operation 651, which comprises providing a core with a cavity through a thickness of the core. The operation 651 may similar to the process and structure described with respect to FIG. 6A.

In an embodiment, the process 650 may continue with operation 652, which comprises applying a carrier under the core that spans a width of the cavity. The operation 652 may be similar to the process and structure described with respect to FIG. 6B.

In an embodiment, the process 650 may continue with operation 653, which comprises placing an assembly on the carrier within the cavity. The operation 653 may be similar to the process and structure described with respect to FIG. 6C.

In an embodiment, the process 650 may continue with operation 654, which comprises filling the cavity with a fill layer. The operation 654 may be similar to the process and structure described with respect to FIG. 6D.

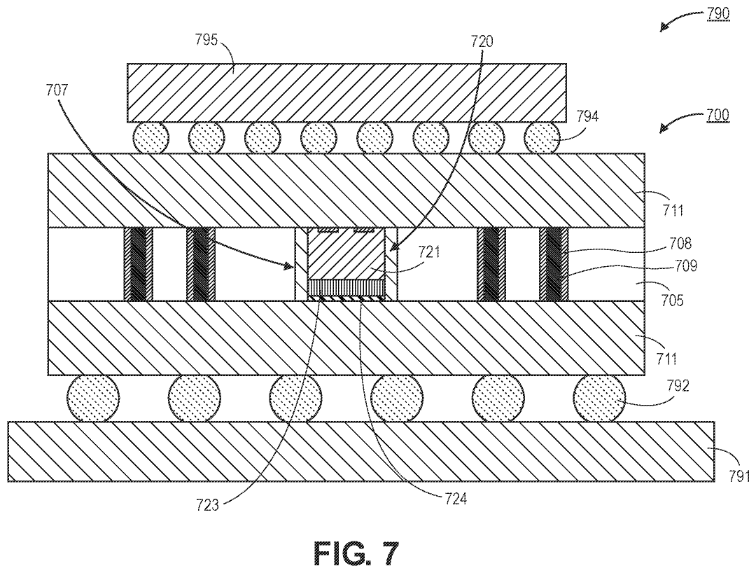

Referring now to FIG. 7, a cross-sectional illustration of an electronic system 790 is shown, in accordance with an embodiment. In an embodiment, the electronic system 790 comprises a board, such as a printed circuit board (PCB), a motherboard, or the like. In an embodiment, the board 790 is coupled to a package substrate 700 by interconnects 792. The interconnects 792 may be second level interconnects (SLIs), such as solder balls, sockets, pins, or the like.

In an embodiment, the package substrate 700 may be similar to any of the package substrates described herein. For example, the package substrate 700 may include a core 705 (e.g., a glass core 705 or an organic core 705) with buildup layers 711 above and below the core 705. The core 705 may comprise vias 708. In FIG. 7, the vias 708 are filled with an insulating plug 709. A cavity 707 may be provided through a thickness of the core 705.

In an embodiment, an assembly 720 may be set into the cavity 707. The assembly 720 may be similar to any of the assemblies described in greater detail herein. For example, the assembly 720 may comprise a component substrate 721 that is coupled to a spacer substrate 723. In FIG. 7, the component substrate 721 is fusion bonded to the spacer substrate 723. Though other coupling options may also be used (e.g., adhesive, solder, etc.). In an embodiment, an adhesive layer 724 is provided below the spacer substrate 723. A fill layer 725 may line the assembly 720 and fill a remaining portion of the cavity 707.

In an embodiment, one or more dies 795 may be coupled to the package substrate 700 by interconnects 794. The interconnects 794 may comprise first level interconnects (FLIs), such as solder balls, copper bumps, hybrid bonding interfaces, or the like. The die 795 may be any type of die, such as a central processing unit (CPU), a graphics processing unit (GPU), an XPU, a communications die, a memory die, an application specific integrated circuit (ASIC), a field programmable gate array (FPGA), or the like. In an embodiment, the assembly 720 is electrically coupled to the one or more dies 795 in order to control and/or improve power delivery that is provided to the die 795.

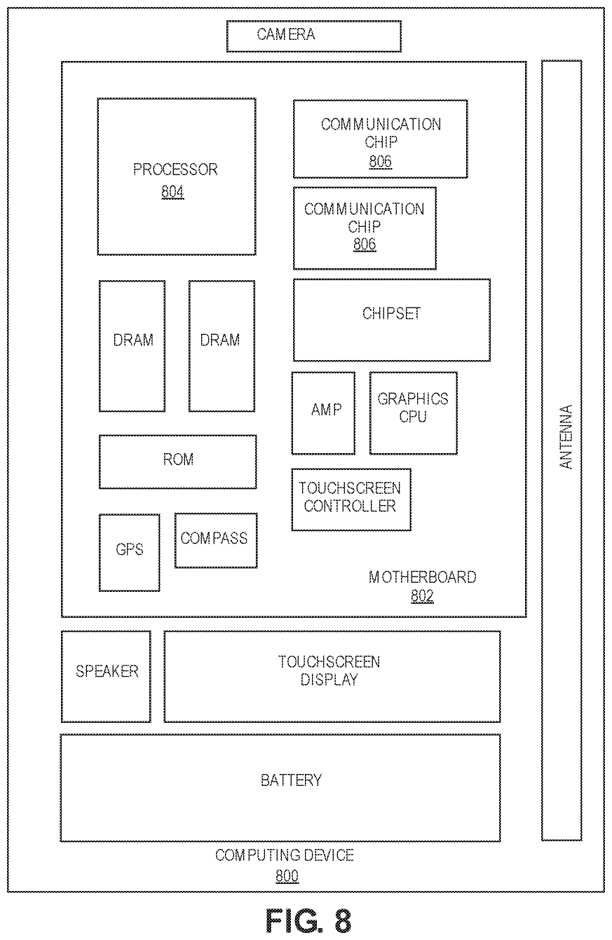

FIG. 8 illustrates a computing device 800 in accordance with one implementation of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the disclosure, the integrated circuit die of the processor may be part of an electronic package that includes a core with an embedded assembly that includes a component substrate bonded to a spacer substrate, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the disclosure, the integrated circuit die of the communication chip may be part of an electronic package that includes a core with an embedded assembly that includes a component substrate bonded to a spacer substrate, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.
Example 1: an apparatus, comprising: a first substrate with a first material composition, wherein the first substrate comprises a passive electrical device; a second substrate coupled to the first substrate, wherein the second substrate has a second material composition; and a layer over a surface of the second substrate opposite from the first substrate, wherein the layer is electrically insulating.
Example 2: the apparatus of Example 1, wherein the first material composition is substantially similar to the second material composition.
Example 3: the apparatus of Example 2, wherein the first substrate directly contacts the second substrate.
Example 4: the apparatus of Examples 1-3, wherein the first substrate is coupled to the second substrate by an adhesive.
Example 5: the apparatus of Examples 1-4, wherein the first material composition is different than the second material composition.
Example 6: the apparatus of Examples 1-5, wherein the first substrate has a first thickness, and wherein the second substrate has a second thickness that is smaller than the first thickness.
Example 7: the apparatus of Examples 1-6, wherein the passive electrical device comprises an inductor, a capacitor, or a resistor.
Example 8: the apparatus of Examples 1-7, wherein the layer is an adhesive material.
Example 9: an apparatus, comprising: a first substrate with a first surface and a second surface opposite from the first surface, and wherein the first substrate comprises a passive electrical device; a first layer on the first surface of the first substrate, wherein the first layer comprises a first metallic material; a second substrate coupled to the first substrate, wherein the second substrate has a third surface and a fourth surface opposite from the third surface; a second layer on the third surface of the second substrate, wherein the second layer comprises a second metallic material; and a third layer between the first layer and the second layer, wherein the third layer comprises a third metallic material that is different than the first metallic material and the second metallic material.
Example 10: the apparatus of Example 9, wherein the third metallic material comprises a solder.
Example 11: the apparatus of Example 9 or Example 10, wherein the first metallic material and the second metallic material comprise one or more of titanium, nickel, or gold.
Example 12: the apparatus of Examples 9-11, wherein the passive electrical device comprises an inductor, a capacitor, or a resistor.
Example 13: the apparatus of Examples 9-12, wherein the first substrate has a first thickness and the second substrate has a second thickness that is smaller than the first thickness.
Example 14: the apparatus of Examples 9-13, wherein the first substrate comprises silicon.
Example 15: the apparatus of Examples 9-14, wherein the first layer comprises a plurality of distinct sub-layers with different metal compositions.
Example 16: an apparatus, comprising: a board; a package substrate coupled to the board, wherein the package substrate comprises: a core with a cavity through a thickness of the core; and an assembly in the cavity, wherein the assembly comprises: a component comprising a passive electrical device; and a spacer coupled to the component, wherein a thickness of the assembly is approximately equal to a thickness of the core; and a die coupled to the package substrate.
Example 17: the apparatus of Example 16, wherein the component directly contacts the spacer.
Example 18: the apparatus of Example 16 or Example 17, wherein the component is coupled to the spacer by an adhesive layer.
Example 19: the apparatus of Examples 16-18, wherein the component is coupled to the spacer by a solder.
Example 20: the apparatus of Examples 16-19, wherein the apparatus is part of a personal computer, a server, a mobile device, a tablet, or an automobile.

What is claimed is:

1. An apparatus, comprising:
a first substrate with a first material composition, wherein the first substrate comprises a passive electrical device;
a second substrate coupled to the first substrate, wherein the second substrate has a second material composition; and
a layer over a surface of the second substrate opposite from the first substrate, wherein the layer is electrically insulating.

2. The apparatus of claim 1, wherein the first material composition is substantially similar to the second material composition.

3. The apparatus of claim 2, wherein the first substrate directly contacts the second substrate.

4. The apparatus of claim 1, wherein the first substrate is coupled to the second substrate by an adhesive.

5. The apparatus of claim 1, wherein the first material composition is different than the second material composition.

6. The apparatus of claim 1, wherein the first substrate has a first thickness, and wherein the second substrate has a second thickness that is smaller than the first thickness.

7. The apparatus of claim 1, wherein the passive electrical device comprises an inductor, a capacitor, or a resistor.

8. The apparatus of claim 1, wherein the layer is an adhesive material.

9. An apparatus, comprising:
a first substrate with a first surface and a second surface opposite from the first surface, and wherein the first substrate comprises a passive electrical device;
a first layer on the first surface of the first substrate, wherein the first layer comprises a first metallic material;
a second substrate coupled to the first substrate, wherein the second substrate has a third surface and a fourth surface opposite from the third surface;
a second layer on the third surface of the second substrate, wherein the second layer comprises a second metallic material; and
a third layer between the first layer and the second layer, wherein the third layer comprises a third metallic material that is different than the first metallic material and the second metallic material.

10. The apparatus of claim 9, wherein the third metallic material comprises a solder.

11. The apparatus of claim 9, wherein the first metallic material and the second metallic material comprise one or more of titanium, nickel, or gold.

12. The apparatus of claim 9, wherein the passive electrical device comprises an inductor, a capacitor, or a resistor.

13. The apparatus of claim 9, wherein the first substrate has a first thickness and the second substrate has a second thickness that is smaller than the first thickness.

14. The apparatus of claim 9, wherein the first substrate comprises silicon.

15. The apparatus of claim 9, wherein the first layer comprises a plurality of distinct sub-layers with different metal compositions.

16. An apparatus, comprising:
a board;
a package substrate coupled to the board, wherein the package substrate comprises:
a core with a cavity through a thickness of the core; and
an assembly in the cavity, wherein the assembly comprises:
a component comprising a passive electrical device; and
a spacer coupled to the component, wherein a thickness of
the assembly is approximately equal to a thickness of the core; and
a die coupled to the package substrate.

17. The apparatus of claim 16, wherein the component directly contacts the spacer.

18. The apparatus of claim 16, wherein the component is coupled to the spacer by an adhesive layer.

19. The apparatus of claim 16, wherein the component is coupled to the spacer by a solder.

20. The apparatus of claim 16, wherein the apparatus is part of a personal computer, a server, a mobile device, a tablet, or an automobile.
